(19) United States
(12) Patent Application Publication
(10) Pub. No.: US 2025/0167436 A1
(43) Pub. Date: May 22, 2025

(54) COMMUNICATION APPARATUS

(71) Applicant: KYOCERA CORPORATION, Kyoto-shi, Kyoto (JP)

(72) Inventors: Tadashi NAGASAWA, Kyoto-shi, Kyoto (JP); Youhei MURAKAMI, Kyoto-shi, Kyoto (JP); Jun KURODA, Kyoto-shi, Kyoto (JP); Satoshi KAWAJI, Kyoto-shi, Kyoto (JP)

(21) Appl. No.: 18/836,377

(22) PCT Filed: Feb. 6, 2023
(86) PCT No.: PCT/JP2023/003854

§ 371 Date: Feb. 5, 2025

(30) Foreign Application Priority Data
Feb. 9, 2022 (JP) 2022-018668

(51) Int. Cl. H01Q 1/42

(52) U.S. Cl. CPC H01Q 1/42

(57) ABSTRACT

A communication apparatus includes a substrate, an antenna unit, and a covering part. The antenna unit is positioned on at least one main surface of the substrate. The covering part is positioned on the main surface of the substrate so as to be in contact with at least a part of an upper portion of the antenna unit.

### RELATED APPLICATIONS

This application is a national stage application, filed under 35 U.S.C. § 371, of International Patent Application No. PCT/JP2023/003854, filed on Feb. 6, 2023, and claims priority under 35 U.S.C. § 119(a) and 35 U.S.C. § 365(b) from Japanese Patent Application No. 2022-018668, filed Feb. 9, 2022; the above applications are incorporated by reference herein in their entirety.

### TECHNICAL FIELD

Various embodiments of the present disclosure relate to communication apparatuses.

### BACKGROUND

Radar apparatuses can be used for vehicle-to-vehicle communication of an automobile, peripheral monitoring, and the like. In such radar apparatuses, an antenna unit is generally covered with a radome (covering part). In such a radome, a space is present between an upper portion of the antenna unit and the radome.

### SUMMARY

A communication apparatus according to the present disclosure includes a substrate, an antenna unit, and a covering part. The antenna unit is positioned on at least one main surface of the substrate. The covering part is positioned on the main surface of the substrate so as to be in contact with at least a part of an upper portion of the antenna unit.

### BRIEF DESCRIPTION OF THE DRAWINGS

FIG. 1 is an explanatory view illustrating a communication apparatus according to an embodiment of the present disclosure.

### DETAILED DESCRIPTION

When a space portion (air layer) is present between the upper portion of the antenna unit and the radome as in the communication apparatus of the related art, moisture is likely to be generated due to a temperature change of air in the space portion. Due to this moisture, the metallic antenna unit is likely to deteriorate. Therefore, there is a need for a communication apparatus in which moisture is less likely to be generated due to changes in temperature and an antenna unit is less likely to deteriorate.

As described above, in the communication apparatus according to the present disclosure, the covering part is positioned on the main surface of the substrate so as to be in contact with at least a part of the upper portion of the antenna unit. Therefore, there is no space (air layer) between the upper portion of the antenna unit and the covering part. Therefore, in the communication apparatus according to the present disclosure, moisture caused by air is less likely to be generated between the antenna unit and the covering part, and the antenna unit is less likely to deteriorate. In the present specification, “no air layer is present” includes a case where a gap that cannot be avoided during manufacturing is present between the upper portion of the antenna unit and the covering part.

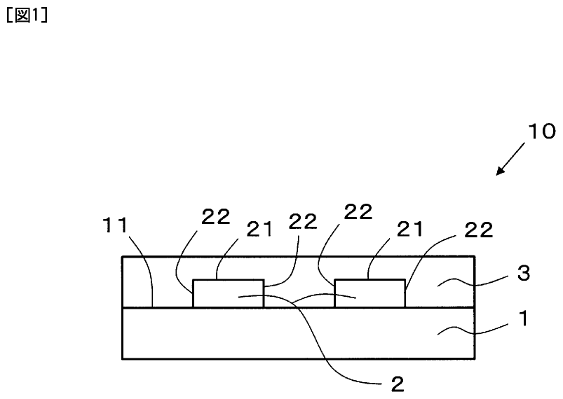

A communication apparatus according to an embodiment of the present disclosure will be described with reference to FIG. 1. FIG. 1 is an explanatory view illustrating a communication apparatus 10 according to an embodiment of the present disclosure.

The communication apparatus 10 according to an embodiment of the present disclosure includes a substrate 1, an antenna unit 2, and a covering part 3. The substrate 1 included in the communication apparatus 10 according to the embodiment is not limited as long as it is a substrate generally used for a communication apparatus.

Examples of such a substrate 1 may include a circuit board such as a printed board. Specifically, the substrate 1 has a structure in which insulating layers and wiring conductor layers are alternately stacked. The insulating layer is made of a resin such as an epoxy resin, a bismaleimide-triazine resin, a polyimide resin, or a polyphenylene ether resin. An insulating fabric material as a reinforcing material, such as glass fiber, glass non-woven fabric, aramid non-woven fabric, aramid fiber, or polyester fiber, may be included in the substrate 1. In addition, an inorganic filler made of, for example, silica, barium sulfate, talc, clay, glass, calcium carbonate, or titanium oxide may be dispersed in the substrate 1. Here, an insulating layer including an organic resin is taken as an example, but in the present disclosure, the insulating layer may be made of not only an organic resin but also ceramics. The wiring conductor layer is made of a metal such as copper.

A thickness and a size of the substrate 1 are not limited as long as the antenna unit 2 can be disposed on at least one main surface 11. The thickness and size of the substrate 1 are appropriately set depending on the application of the communication apparatus 10.

The antenna unit 2 is a member that transmits and receives radio waves, and is disposed on at least one main surface 11 of the substrate 1. In the communication apparatus 10 according to the embodiment, the frequency of radio waves that can be transmitted and received is not limited and is appropriately set depending on the application thereof. The material used for the antenna unit 2 may be a metal. The metal, in at least one example, has high conductivity. Examples of such a metal may include a base metal such as copper or nickel, a noble metal such as gold, platinum or silver, or aluminum or brass.

As described above, in the communication apparatus of the present disclosure, there is no air layer between an upper portion 21 of the metallic antenna unit 2 and the covering part 3. In other words, at least a part of the upper portion 21 of the metallic antenna unit 2 is in contact with the covering part 3. For this reason, a base metal such as copper, which is inferior in corrosion resistance to a noble metal, can be suitably used for the antenna unit 2. In this case, a surface of the metal constituting the antenna unit 2 may be exposed. Note that an organic resin layer originally formed on the material of the antenna unit 2 and subjected to silane coupling treatment, benzotriazole treatment, or the like may be present on a surface of the antenna unit 2 on a side in contact with the covering part 3. Such an organic resin layer makes it difficult for moisture or the like to enter an interface between the antenna unit 2 and the covering part 3, or makes it easy to repel moisture.

The covering part 3 is positioned on the main surface 11 of the substrate 1 so as to be in contact with the antenna unit 2. In the communication apparatus 10 according to the embodiment, the covering part 3 is in contact with the antenna unit 2 and is also in contact with the substrate 1. That is, no air layer is present between the upper portion 21 of the antenna unit 2 and the covering part 3. With such a configuration, in the communication apparatus 10 according to the embodiment, moisture caused by air is less likely to be generated, and the antenna unit 2 is less likely to deteriorate. Furthermore, as in the communication apparatus 10 according to the embodiment, when the covering part 3 is in contact with the upper portion 21 and a side portion 22 of the antenna unit 2, it is possible to reduce a possibility that radio waves will be reflected. As a result, attenuation of radio waves can be made less likely to occur. In the present specification, the “air layer” means a layer positioned so that an entire surface of the upper portion 21 of the antenna unit 2 is in contact with air.

The covering part 3 may be disposed at a height at which no air layer is present between the covering part and the substrate 1 and between the covering part and the antenna unit 2. When the covering part 3 is in contact with the substrate 1 and the antenna unit 2, an influence of stress generated between the covering part 3 and the substrate 1 and between the covering part 3 and the antenna unit 2 due to a temperature change around the communication apparatus is reduced. This improves the durability of the communication apparatus.

Furthermore, if a space (air layer) is present between the upper portion of the antenna unit and the radome as in the radome of the related art, a thickness of the space (air layer) (a distance between a lower surface of the radome and an upper surface of the antenna unit), alignment of the antenna unit and the radome, and the like need to be accurate. If a slight error occurs in the thickness or alignment of the space, there is a possibility that the spread of radio waves will be changed. Further, if the thickness of the radome is formed as uniformly as possible with high accuracy, the cost becomes high. When the upper portion 21 of the antenna unit 2 and the covering part 3 are brought into contact with each other, such problems are also solved.

The covering part 3 is formed of, for example, a resin. Examples of such a resin may include a resin containing a cyclic olefin copolymer as a main component, a polyimide resin, and a polyphenylene ether resin. Among these resins, the cyclic olefin copolymer has a low water absorption rate (0.02% or less) and can make it more difficult to generate moisture.

The cyclic olefin copolymer is a polyolefin-based copolymer having a cyclic structure. The cyclic olefin copolymer is obtained by polymerizing a cyclic olefin and another monomer copolymerizable with the cyclic olefin. A ratio of the cyclic olefin to another monomer is not particularly limited. For example, another monomer is used at a ratio of 1 part by mass or more and 100 parts by mass or less with respect to 100 parts by mass of the cyclic olefin.

Examples of the cyclic olefin include a norbornene-based monomer, a cyclic diene-based monomer, and a vinyl alicyclic hydrocarbon-based monomer. Specific examples of the cyclic olefin include norbornene, vinylnorbornene, phenylnorbornene, dicyclopentadiene, tetracyclododecene, cyclopropene, cyclobutene, cyclopentene, cyclohexene, cyclohexadiene, and cyclooctadiene. These cyclic olefins may be used alone, or in combination of two or more thereof.

Examples of another monomer copolymerizable with the cyclic olefin may include a chain olefin, an acrylic acid, a methacrylic acid, an acrylic acid ester, a methacrylic acid ester, an aromatic vinyl compound, an unsaturated nitrile, and an aliphatic conjugated diene. Specific examples of such a monomer may include ethylene, propylene, butene, acrylic acid, methacrylic acid, fumaric acid, fumaric anhydride, maleic acid, maleic anhydride, methyl acrylate, ethyl acrylate, propyl acrylate, isopropyl acrylate, methyl methacrylate, ethyl methacrylate, propyl methacrylate, isopropyl methacrylate, styrene, vinyl toluene, acrylonitrile, methacrylonitrile, 1,3-butadiene, 2-methyl-1,3-butadiene, and 2,3-dimethyl-1,3-butadiene. Such monomers may be used alone or in combination of two or more thereof.

In the present disclosure, the “resin containing a cyclic olefin copolymer as a main component” refers to a resin containing the above-described cyclic olefin copolymer in an amount of 50 mass % or more except for an additive component described below. That is, the “resin containing a cyclic olefin copolymer as a main component” may be a resin containing only the cyclic olefin copolymer (the cyclic olefin copolymer is 100 mass %), or may be a resin containing the cyclic olefin copolymer and a resin other than the cyclic olefin copolymer.

Examples of the resin other than the cyclic olefin copolymer may include an acrylic resin, an epoxy resin, a phenol resin, a melamine resin, a urea resin, a polyamide, and a polyimide. These resins may be used, for example, alone or in combination of two or more thereof, taking into consideration compatibility with the cyclic olefin copolymer.

Examples of the cyclic olefin copolymer may include a thermoplastic cyclic olefin copolymer and a thermosetting cyclic olefin copolymer. Among these, a cyclic olefin copolymer including a thermosetting cyclic olefin copolymer is, in at least one example, used, and for example, a polymer obtained by compounding a thermoplastic cyclic olefin copolymer and a thermosetting cyclic olefin copolymer may be used as long as heat resistance can be ensured. Among them, the thermoplastic cyclic olefin copolymer is more flexible than the thermosetting resin even in a solid state, so the antenna unit 2 positioned so as to protrude from the substrate 1 can be covered so as to be more closely contacted. Since the composite of the thermoplastic cyclic olefin copolymer and the thermosetting cyclic olefin copolymer contains the thermosetting cyclic olefin copolymer, the composite exhibits heat resistance, making it possible to dispose the communication apparatus 10 in a high-temperature environment (for example, an engine part of an automobile).

The cyclic olefin copolymer may have a relative permittivity of 3 or less at frequencies of 10 GHz or higher and 1 THz or lower. When a cyclic olefin copolymer having such a relative permittivity is used, the covering part 3 can be made relatively thin (for example, 10 mm or less, particularly 5 mm or less). As a result, when the antenna unit 2 is in a state of protruding from a surface of the substrate 1, even if there is a step due to the thickness of the antenna unit 2, a gap is less likely to be formed on a side surface of the step portion (a side surface of the antenna unit 2). The thickness of the covering part 3 is, in at least one example, 0.1 mm or greater in order to improve moisture resistance and enhance strength as a protective film. Furthermore, the communication apparatus can be made thin.

The covering part 3 may have an in-plane (X-Y direction) amount of change in relative permittivity of 0.005 or less. In-plane (X-Y direction) is a range in which an area of the substrate 1 is maximized in a range of a plane formed by an X axis and a Y axis when the substrate 1 including the antenna unit 2 is viewed in a plan view and coordinates in the X direction and the Y direction which are virtually orthogonal to each other are defined on the surface of the substrate 1. When the in-plane amount of change in relative permittivity is 0.005 or less, the anisotropy of the transmission characteristics and reflection characteristics of input and output radio waves decreases. As a result, for example, the anisotropy of the horizontally polarized waves of the antenna unit 2 can be reduced.

The thickness of the covering part 3 is not limited as long as the covering part 3 can cover the antenna unit 2. The thickness of the covering part 3 may be partially non-uniform. In other words, the covering part 3 may include a portion having a non-uniform thickness in a region including the antenna unit 2 and the periphery thereof. For example, in the covering part 3, a region where the antenna unit 2 is disposed may be thicker than other regions. In this way, when the thickness of the covering part 3 is large in the region where the antenna unit 2 is disposed, the antenna unit 2 can be efficiently protected from mechanical impacts. In the present specification, the “thickness of the covering part 3” refers to a dimension of the covering part 3 in a direction perpendicular to the one main surface 11 of the substrate 1.

A method of manufacturing the communication apparatus 10 according to an embodiment is not limited, and the communication apparatus can be realized, for example, through the following method. First, as described above, the substrate 1 having a structure in which insulating layers and wiring conductor layers are alternately stacked is prepared. Next, for example, the antenna unit 2 is mounted on at least one main surface 11 of the substrate 1. Next, the covering part 3 is formed so as to be in contact with the antenna unit 2.

The communication apparatus is not limited to the structure in which the antenna unit 2 is mounted on the substrate 1. In order to further reduce a height of the antenna unit 2, a metal film serving as the antenna unit 2 may be attached to the surface of the substrate 1. Alternatively, a part of the metal film serving as the antenna unit 2 may be buried from the surface of the substrate 1 to a predetermined depth. The structure in which a part of the metal film serving as the antenna unit 2 is buried from the surface of the substrate 1 to a predetermined depth may be a structure close to a so-called printed board type, which is formed by, for example, bonding a metal foil having a predetermined area on a surface of an insulating layer made of an organic resin and performing a pressurizing and heating treatment.

The covering part 3 is formed, for example, by the following method. First, a cyclic olefin copolymer in a form of a sheet or paste is attached to the surface of the substrate 1 including the antenna unit 2. At this time, it is made impossible for a space (air layer) to be formed between the covering part 3 and the antenna unit 2. The covering part 3 is, in at least one example, attached to the main surface 11 on which the antenna unit 2 is disposed, out of the surfaces of the substrate 1 on which the antenna unit 2 is mounted, without a gap. Thereafter, the cyclic olefin copolymer is cured to form the covering part 3.

The communication apparatus 10 according to the embodiment realized as described above is mounted on, for example, a radar apparatus for vehicle-to-vehicle communication of an automobile, a radar apparatus for peripheral monitoring, or the like.

The communication apparatus according to the present disclosure is not limited to the communication apparatus 10 according to the embodiment described above. In the communication apparatus according to the present disclosure, the covering part may be positioned on the main surface of the substrate so as to be in contact with at least a part of the upper portion of the antenna unit, or the covering part may be in contact with an entire surface of the upper portion of the antenna unit. When the covering part is in contact with the entire surface of the upper portion of the antenna unit, no air layer is present on the upper portion of the antenna unit. As a result, attenuation of radio waves radiated from the antenna unit and radio waves received by the antenna unit can be made less likely to occur.

### REFERENCE SIGNS

1 Substrate
11 Main surface
2 Antenna unit
21 Upper portion
22 Side portion
3 Covering part
10 Communication apparatus

What is claimed is:

1. A communication apparatus comprising:
a substrate;
an antenna unit; and
a covering part,
wherein the antenna unit is positioned on at least one main surface of the substrate, and
the covering part is positioned on the at least one main surface of the substrate so as to be in contact with at least a part of an upper portion of the antenna unit.

2. The communication apparatus according to claim 1, wherein the covering part is in contact with an entire surface of the upper portion of the antenna unit.

3. The communication apparatus according to claim 1, wherein the covering part is in contact with the upper portion and a side portion of the antenna unit.

4. The communication apparatus according to claim 1, wherein the covering part is made of a resin containing a cyclic olefin copolymer as a main component.

5. The communication apparatus according to claim 4, wherein the cyclic olefin copolymer has a relative permittivity of 3 or less at frequencies of 10 GHz or higher and 1 THz or lower.

6. The communication apparatus according to claim 4, wherein the cyclic olefin copolymer comprises a thermosetting cyclic olefin copolymer.

7. The communication apparatus according to claim 1, wherein the covering part has an in-plane (X-Y direction) amount of change in relative permittivity of 0.005 or less.

8. The communication apparatus according to claim 1, wherein, in the covering part, a region in which the antenna unit is disposed is thicker than other regions.
